(19) United States
(12) Patent Application Publication
(10) Pub. No.: US 2026/0090021 A1
(43) Pub. Date: Mar. 26, 2026

(54) DEEP VIA TO PRESERVE SUBSTRATE

(71) Applicant: International Business Machines Corporation, Armonk, NY (US)

(72) Inventors: Chanro Park, Clifton Park, NY (US); Ruilong Xie, Niskayuna, NY (US); Tao Li, Slingerlands, NY (US); Kisik Choi, Watervliet, NY (US); HUIMEI ZHOU, Albany, NY (US); Xiaoming Yang, Clifton Park, NY (US); LEI ZHUANG, Ridgefield, CT (US); Ravikumar Ramachandran, Pleasantville, NY (US)

(21) Appl. No.: 18/891,018

(22) Filed: Sep. 20, 2024

(51) Int. Cl. H01L 29/423; H01L 21/768; H01L 23/522; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10W 20/056; H10W 20/089; H10W 20/42

(57) ABSTRACT

A microelectronic structure that includes a nanosheet FET located on a substrate where the nanosheet FET includes a source/drain. A frontside source/drain contact located on a frontside surface of the source/drain. A deep via located adjacent to the frontside source/drain contact, where the frontside source/drain contact is connected to the deep via. The deep via extends downwards to a backside region of the nanosheet FET. A deep via extension is located on a backside surface of the deep via, where the deep via extension is wider than the backside surface of the deep via.

### BACKGROUND

The present invention generally relates to the field of microelectronics, and more particularly to forming a deep via to preserve a substrate.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form a backside via while maintaining enough space for passive device formation.

### BRIEF SUMMARY

Additional aspects and/or advantages will be set forth in part in the description which follows and, in part, will be apparent from the description, or may be learned by practice of the invention.

A microelectronic structure that includes a nanosheet FET located on a substrate where the nanosheet FET includes a source/drain. A frontside source/drain contact located on a frontside surface of the source/drain. A deep via located adjacent to the frontside source/drain contact, where the frontside source/drain contact is connected to the deep via. The deep via extends downwards to a backside region of the nanosheet FET. A deep via extension is located on a backside surface of the deep via, where the deep via extension is wider than the backside surface of the deep via.

A microelectronic structure includes a nanosheet FET located on a substrate where the nanosheet FET includes a source/drain. A frontside source/drain contact located on a frontside surface of the source/drain. A deep via located adjacent to the frontside source/drain contact. The deep via includes a conductive via and a deep via liner, where the deep via liner is located around the conductive via. The frontside source/drain contact is connected to the deep via. The deep via extends downwards to a backside region of the nanosheet FET. A deep via extension is located on a backside surface of the deep via, where the deep via extension is wider than the backside surface of the deep via.

A microelectronic structure includes a nanosheet FET located on a substrate where the nanosheet FET includes a source/drain. A frontside source/drain contact located on a frontside surface of the source/drain. A deep via located adjacent to the frontside source/drain contact. The deep via includes a conductive via and a deep via liner, where the deep via liner is located around the conductive via. The frontside source/drain contact is connected to the deep via. The deep via extends downwards to a backside region of the nanosheet FET. A deep via extension is located on a backside surface of the deep via, where the deep via extension is wider than the backside surface of the deep via. A first backside interlayer dielectric layer is located on a backside surface of the substrate. A second backside interlayer dielectric layer is located on a backside surface of the first interlayer dielectric layer.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross section Y1 of the gate region after initial processing and the formation of a gate cut, in accordance with the embodiment of the present invention.

FIG. 3 illustrates a cross section Y2 of the source/drain region after initial processing and the formation of a gate cut, in accordance with the embodiment of the present invention.

FIG. 4 illustrates a top-down view of a plurality of nanosheet transistors after formation of a deep trench in the gate cut, in accordance with the embodiment of the present invention.

FIG. 5 illustrates a cross section Y1 of the gate region after formation of a deep trench in the gate cut, in accordance with the embodiment of the present invention.

FIG. 6 illustrates a cross section Y2 of the source/drain region after formation of a deep trench in the gate cut, in accordance with the embodiment of the present invention.

FIG. 7 illustrates a top-down view of a plurality of nanosheet transistors after formation of the deep via, in accordance with the embodiment of the present invention.

FIG. 8 illustrates a cross section Y1 of the gate region after formation of the deep via, in accordance with the embodiment of the present invention.

FIG. 9 illustrates a cross section Y2 of the source/drain region after formation of the deep via, in accordance with the embodiment of the present invention.

FIG. 10 illustrates a top-down view of a plurality of nanosheet transistors after additional frontside processing of the nanosheet FETs, in accordance with the embodiment of the present invention.

FIG. 11 illustrates a cross section Y1 of the gate region after additional frontside processing of the nanosheet FETs, in accordance with the embodiment of the present invention.

FIG. 12 illustrates a cross section Y2 of the source/drain region after additional frontside processing of the nanosheet FETs, in accordance with the embodiment of the present invention.

FIG. 13 illustrates a cross section Y1 of the gate region after flipping over the nanosheet FETs for backside processing and the removal of the first substrate, in accordance with the embodiment of the present invention.

FIG. 14 illustrates a cross section Y2 of the source/drain region after flipping over the nanosheet FETs for backside processing and the removal of the first substrate, in accordance with the embodiment of the present invention.

FIG. 15 illustrates a cross section Y1 of the gate region after formation of a backside sacrificial spacer and formation of a first backside interlayer dielectric layer, in accordance with the embodiment of the present invention.

FIG. 16 illustrates a cross section Y2 of the source/drain region after formation of a backside sacrificial spacer and formation of a first backside interlayer dielectric layer, in accordance with the embodiment of the present invention.

FIG. 17 illustrates a cross section Y1 of the gate region after removal of the backside sacrificial spacer and formation of a spacer trench, in accordance with the embodiment of the present invention.

FIG. 18 illustrates a cross section Y2 of the source/drain region after removal of the backside sacrificial spacer and formation of a spacer trench, in accordance with the embodiment of the present invention.

FIG. 19 illustrates a cross section Y1 of the gate region after formation of a backside spacer, in accordance with the embodiment of the present invention.

FIG. 20 illustrates a cross section Y2 of the source/drain region after formation of a backside spacer, in accordance with the embodiment of the present invention.

FIG. 21 illustrates a cross section Y1 of the gate region after formation of an initial backside contact trench, in accordance with the embodiment of the present invention.

FIG. 22 illustrates a cross section Y2 of the source/drain region after formation of an initial backside contact trench, in accordance with the embodiment of the present invention.

FIG. 23 illustrates a cross section Y1 of the gate region after formation of a widened backside contact trench, in accordance with the embodiment of the present invention.

FIG. 24 illustrates a cross section Y2 of the source/drain region after formation of a widened backside contact trench, in accordance with the embodiment of the present invention.

FIG. 25 illustrates a cross section Y1 of the gate region after formation of a widened deep via extension, in accordance with the embodiment of the present invention.

FIG. 26 illustrates a cross section Y2 of the source/drain region after formation of a widened deep via extension, in accordance with the embodiment of the present invention.

FIG. 27 illustrates a cross section Y1 of the gate region after formation of a second backside interlayer dielectric layer and formation of a backside metal line, in accordance with the embodiment of the present invention.

FIG. 28 illustrates a cross section Y2 of the source/drain region after formation a second backside interlayer dielectric layer and formation of a backside metal line, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example “embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration. ” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The term “a plurality” can be understood to include any integer number greater than or equal to two, i.e., two, three, four, five, etc. The term “connection” can include both indirect “connection” and a direct “connection. ”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed to the formation of a deep backside via in a nanosheet FET to preserve the substrate where the nanosheet FET is located. A gate cut is formed in the region located between two adjacent nanosheet devices active regions. A deep trench is formed in a portion of the gate cut where the deep trench extends downwards past the underlying substrate. The portion of the backside via is relatively narrow towards the backside region since the via is formed by a frontside etching process, meaning that the width of the trench is narrower at the backside region when compared to the frontside region. To increase a backside contact surface area of the backside via, a portion of the backside via is removed to form a backside trench. The backside trench is widened and filled with a conductive metal to form a wider region of the backside.

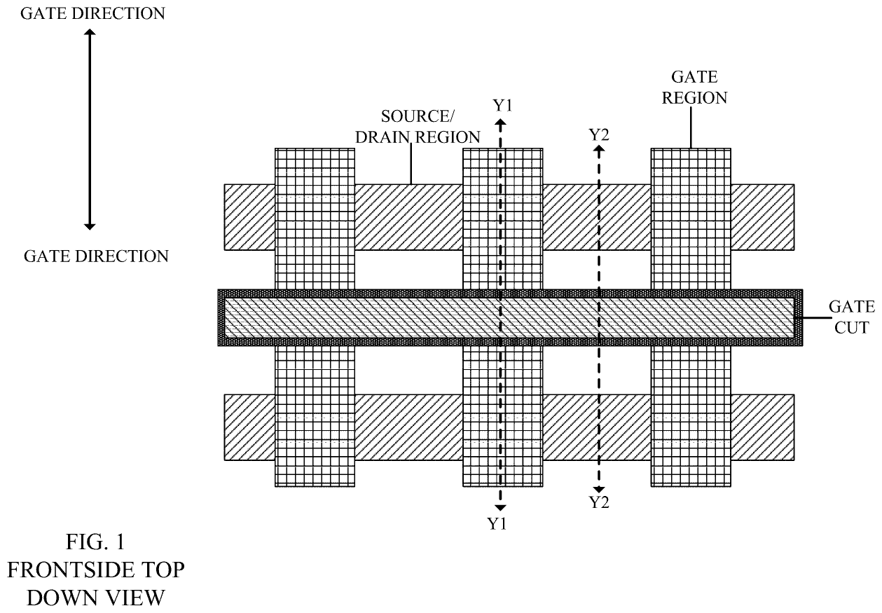

FIG. 1 illustrates a top-down view of multiple devices, in accordance with the embodiment of the present invention. Cross section Y1 is a cross section through a gate region that spans across multiple adjacent nanosheet transistors or field-effect-transistors. Cross section Y2 is a cross section through a source/drain region that spans across multiple adjacent nanosheet transistors or field-effect-transistors. Cross-section Y1 and Y2 are parallel to the gate direction.

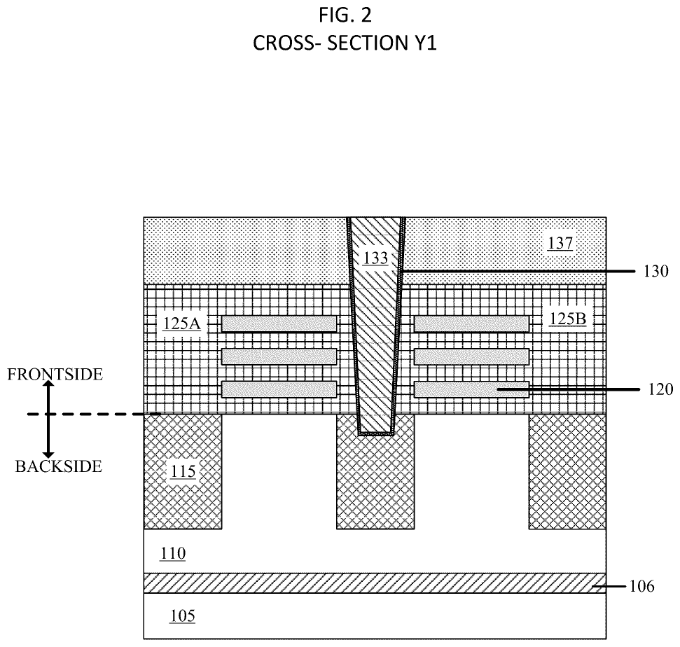

Referring now to FIG. 2, and 3, a structure is shown during an intermediate step of a method of fabricating after initial processing and the formation of gate cut, where the gate cut includes a liner 130 and dielectric fill 133. FIG. 2 illustrates the gate region where the nanosheet FETs include a first substrate 105, an etch stop 106, a second substrate 110, a shallow trench isolation layer 115, a plurality of channel layers 120, a first gate 125A, a second gate 125B, a gate cut liner 130, a dielectric fill 133, and a frontside interlayer dielectric layer 137.

The first substrate 105 and the second substrate 110 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of first substrate 105 and the second substrate 110. In some embodiments, first substrate 105 and the second substrate 110 includes both semiconductor materials and dielectric materials. The semiconductor first substrate 105 and the second substrate 110 may also comprise an organic semiconductor or a layered semiconductor such as, for example, Si/SiGe, a silicon-on-insulator or a SiGe-on-insulator. A portion or the entire semiconductor first substrate 105 and the second substrate 110 may also be comprised of an amorphous, polycrystalline, or monocrystalline. The semiconductor first substrate 105 and the second substrate 110 may be doped, undoped or contain doped regions and undoped regions therein. The plurality of channel layers 120 can be comprised of, for example, Si. A gate cut is formed between adjacent nanosheet FETs as illustrated in FIG. 1, where the gate cut includes a gate cut liner 130 and a dielectric fill 133. The gate cut separates the gate (where it initials extends between the adjacent nanosheet FETs) into a first gate 125A and a second gate 125B. First gate 125A and the second gate 125B can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. The gate cut extends downwards into the shallow trench isolation layer 115 that is located in same level as the second substrate 110.

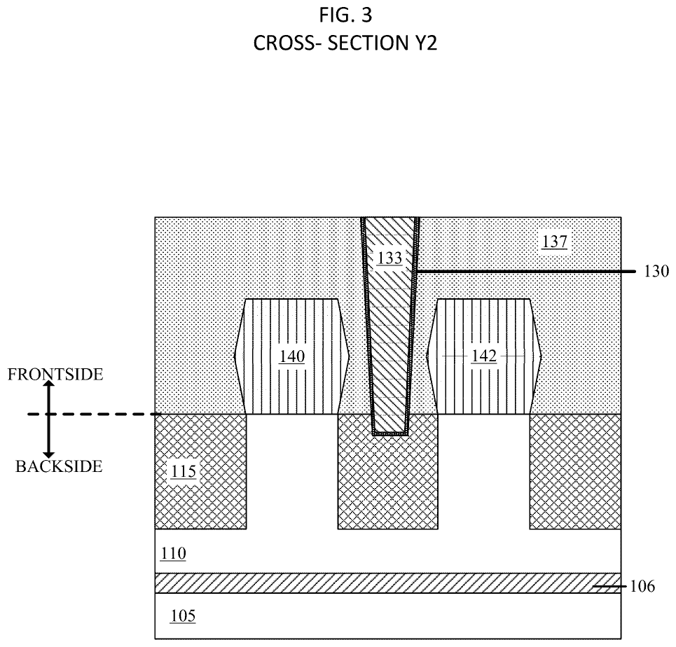

FIG. 3 illustrates a cross-section Y2 that extends through the source/drain region. The source/drain region includes a first source/drain 140 and a second source/drain 142. The gate cut is located between the first source/drain 140 and the second source/drain 142. The first source/drain 140 is associated with a first nanosheet FET and the second source drain 142 is associated with a second nanosheet FET, where the first nanosheet FET is adjacent to the second nanosheet FET.

The first source/drain 140 and the second source/drain 142 are epitaxially grown in the source/drain regions. The first source/drain 140 and the second source/drain 142, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

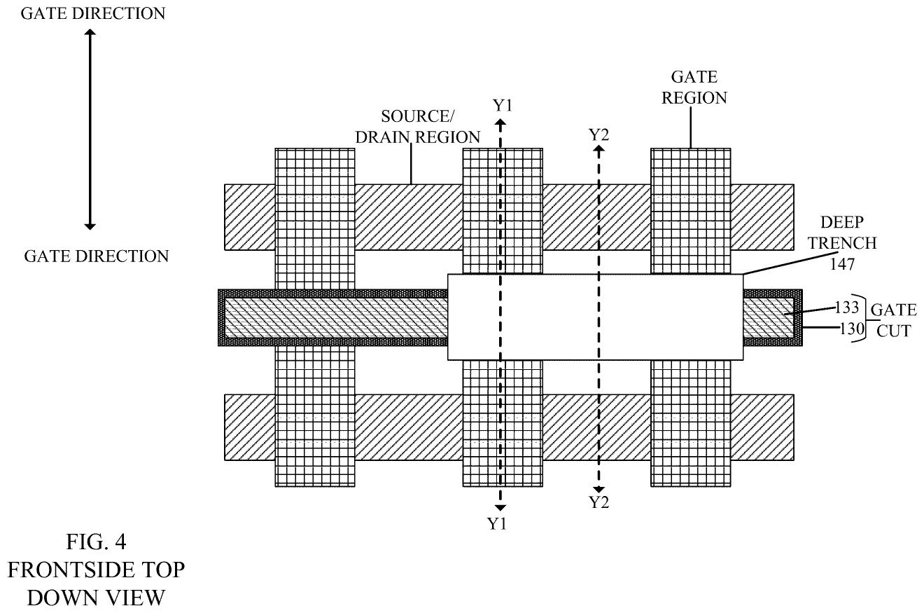

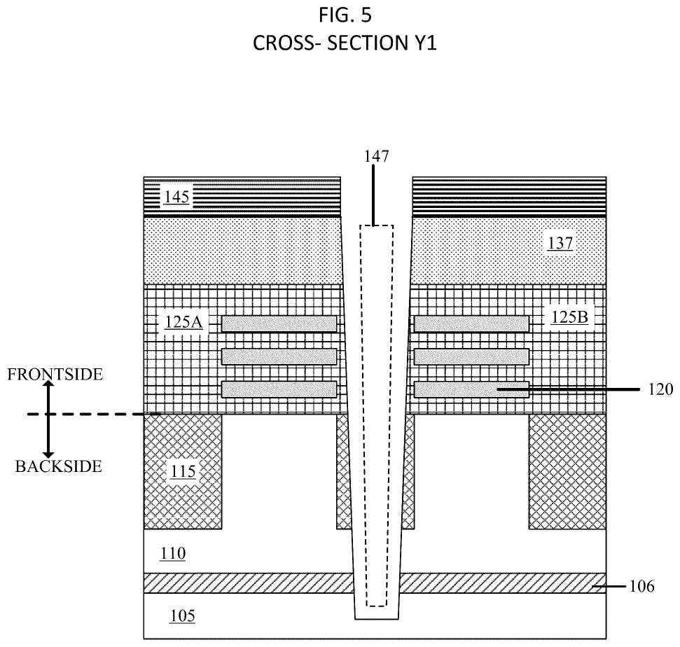

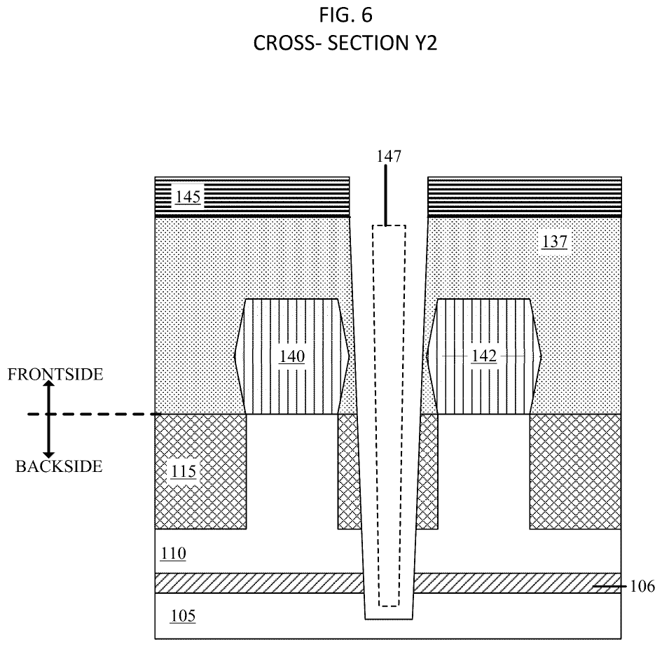

FIGS. 4, 5, and 6 illustrate the processing stage after formation of a deep trench 147 in the gate cut. FIG. 4 illustrates a top-down view of the adjacent nanosheet FETs that shows the deep trench 147 being formed in a gate cut, where the deep trench 147 does not extend across the entire length of the gate cut (which includes gate cut liner 130 and dielectric fill 133). Deep trench 147 is formed in a portion of the gate cut, where the deep trench 147 extends downwards further into the backside region than the gate cut. FIGS. 2 and 3 illustrate where the gate cut extends downwards into the backside region into the shallow trench isolation layer 115. FIGS. 5 and 6 illustrate that deep trench 147 extends downwards past the shallow trench isolation layer 115, past the second substrate 110, and past the etch stop 106 into the first substrate 105.

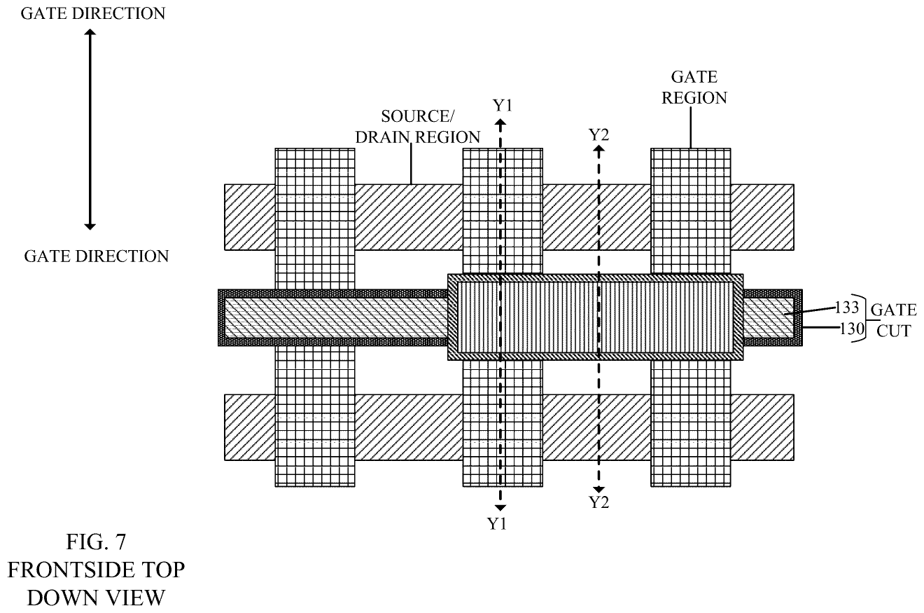

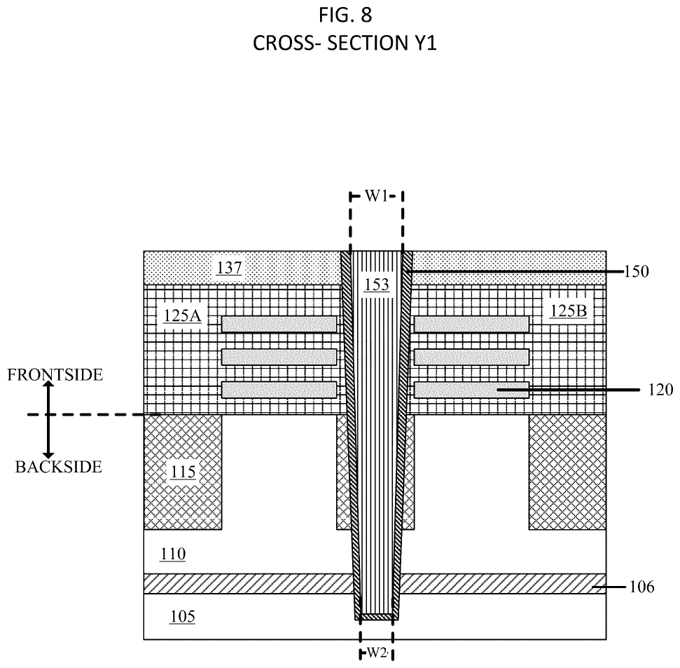

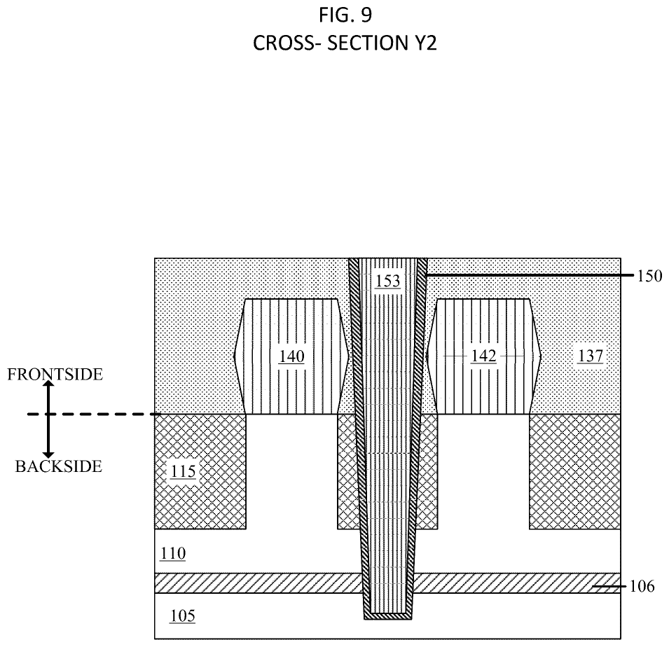

FIGS. 7, 8, and 9 illustrate the processing stage after formation of the deep via. FIG. 7 illustrates a top-down view after formation of the deep via in the location of the deep trench 147. A deep via liner 150 is formed along the sidewalls of the deep trench 147. A deep via 153 is formed by filling the remaining portion of the deep trench 147 with a conductive metal. The deep via 153 has a top width W1, as measured at the top of the deep via 153 in the frontside region. The deep via 153 has a bottom width W2, as measured at the bottom of deep via 153 in the backside region. Top width W1 and the bottom width W2 are measured in parallel to the gate direction. The top width W1 is larger than the bottom width W2.

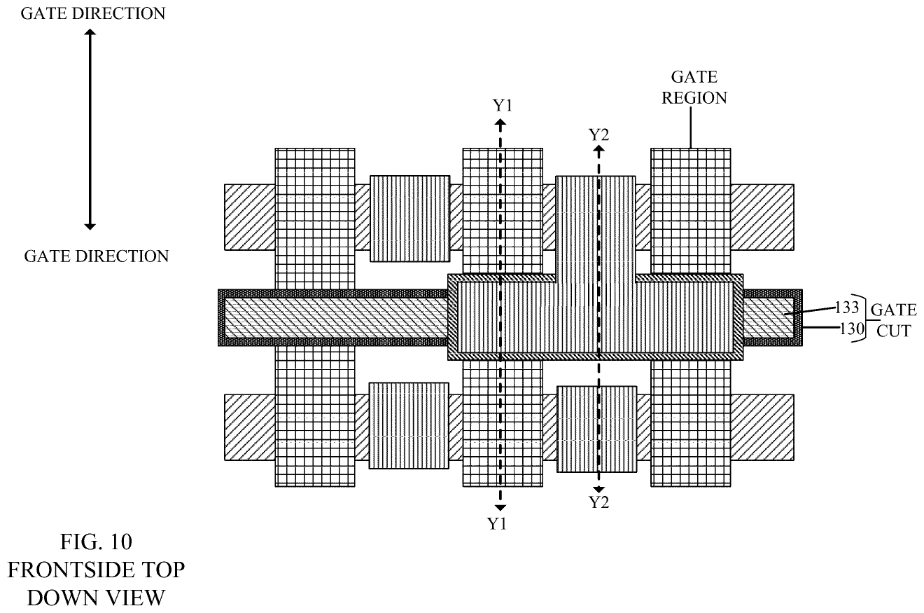

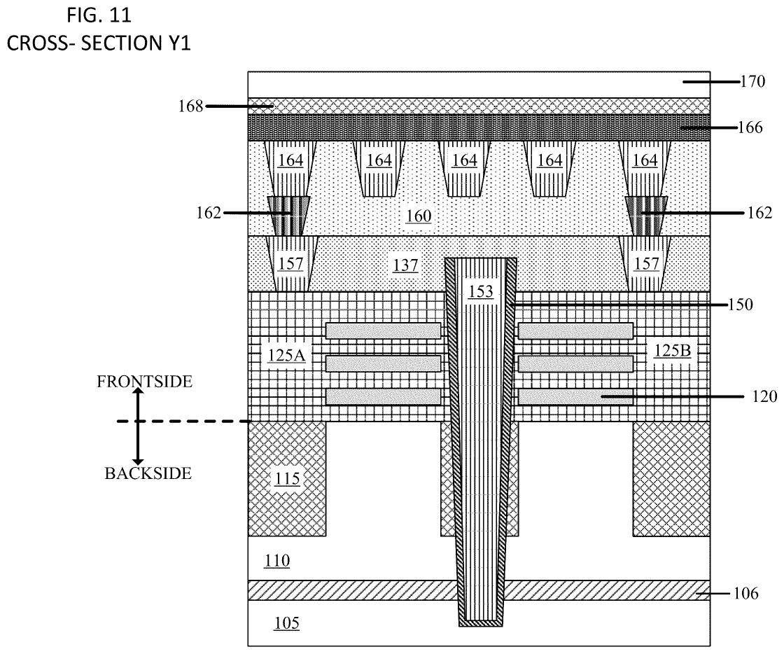

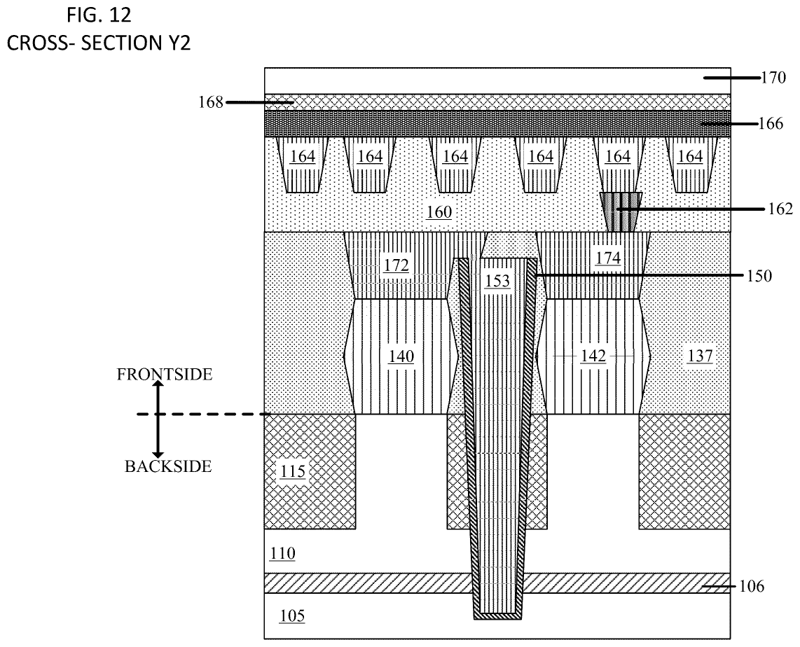

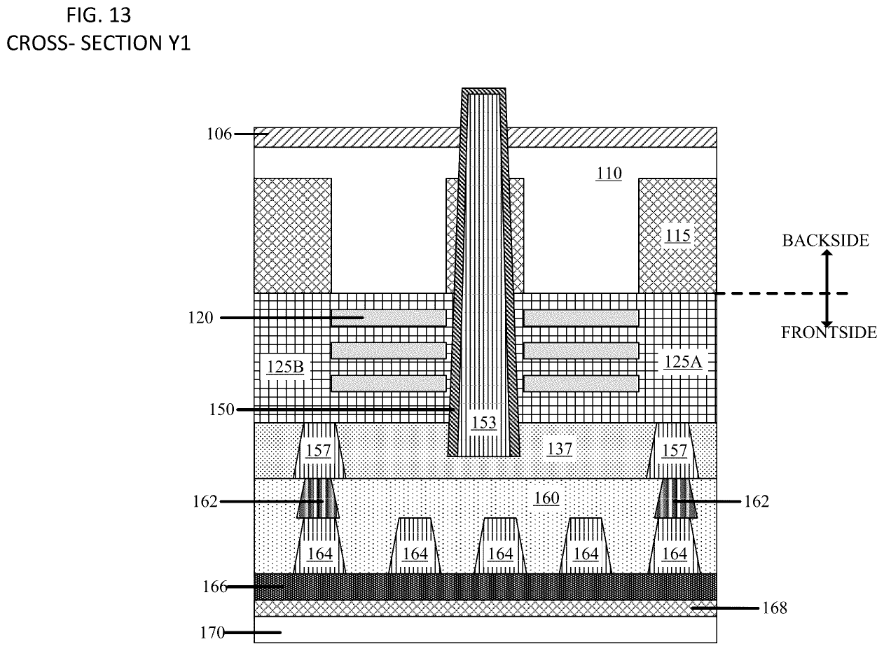

FIGS. 10, 11 and 12 illustrate the processing stage after additional frontside processing of the nanosheet FETs. The height of frontside interlayer dielectric layer 137 is increased such that the frontside interlayer dielectric layer 137 extends over the top of the gate cut and on top of the deep via 153. A plurality of trenches (not shown) are formed in the frontside interlayer dielectric layer 137, where each of the plurality of trenches (not shown) exposes a top surface of an underlying component (for example, first gate 125A, second gate 125B, first source/drain 140, a portion of the deep via, and the second source/drain). These trenches (not shown) are filled with a conductive metal to form gate contacts 157, a first source/drain contact 172, a second source/drain contact 174, and other contacts not shown in the illustrative cross-sections. A gate contact 157 connects to the first gate 125A and another gate contact 157 connects to the second gate 125B. A first source/drain contact 172 is connected to the frontside surface of the first source/drain 140. The first source/drain contact 172 is in further contact with a top surface of the deep via 153. The first source/drain contact 172 extends over the deep via liner 150 to contact the top surface of the deep via 153. A second source/drain contact 174 is connected to the frontside surface of the second source/drain 142. A second frontside interlayer dielectric layer 160 is formed on top of the frontside interlayer dielectric layer 137, on top of the gate contacts 157, on top of the first source/drain contact 172, and on top of the second source/drain contact 174. A plurality of trenches (not shown) is formed in the second frontside interlayer dielectric layer 160. These trenches (not shown) are filled with a conductive metal to form a plurality of connecting vias 162 and a plurality of metal lines 164. Each of the connecting vias 162 connect to one of the gate contacts 157 or the second source/drain contact 174 such that the connecting vias 162 connect these components to one of the plurality of metal lines 164. The plurality of metal lines 164 can be comprised of power lines (VSS or VDD), ground, clock, signal lines, or another type of metal line. A frontside interconnect 166 is formed on top of the plurality of metal lines 164 and on top of the second interlayer dielectric layer 160. The frontside interconnect 166 is also referred to as a back-end-of-the-line layer, which is comprised of one or more layers, one or more metal lines, and/or one or more vias. A bonding oxide 168 is located on top of the frontside interconnect 166. A carrier wafer 170 is located on top of the bonding oxide 168. The carrier wafer 170 allows for the flipping over of the device to allow for the backside processing of the nanosheet FETs. FIGS. 1-12 illustrate the frontside processing of the nanosheet FETs and FIGS. 13-28 illustrate the backside processing of the nanosheet FETs.

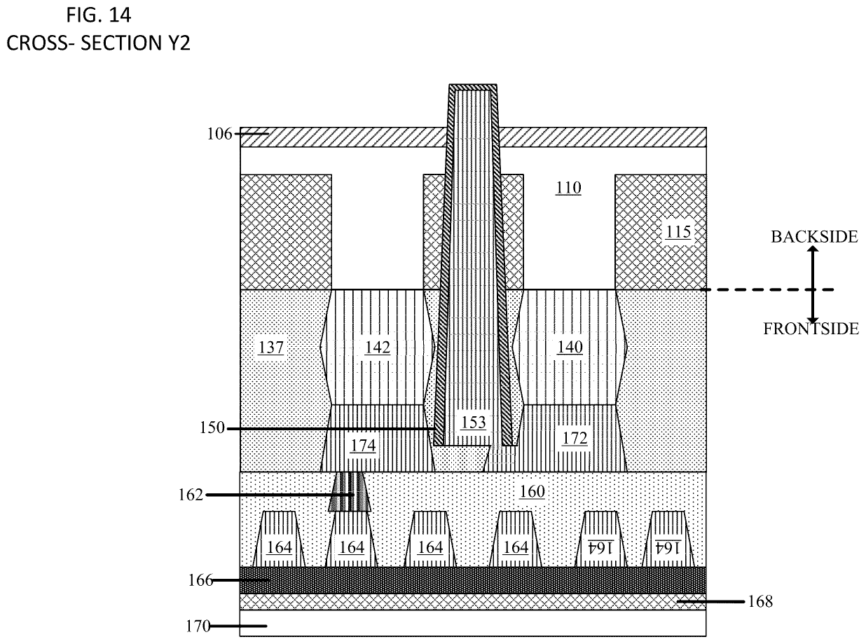

FIGS. 13 and 14 illustrate the processing stage after flipping over the nanosheet FETs for backside processing and the removal of the first substrate 105. The nanosheet FETs are flipped over for backside processing and the first substrate 105 is removed. The removal of the first substrate 105 exposes a portion of the deep via liner 150 that encloses a portion of the deep via 153. FIGS. 13 and 14 illustrate that the deep via liner 150 and the deep via 153 extended past the etch stop 106 in the backside region, thus passing completely through the second substrate 110.

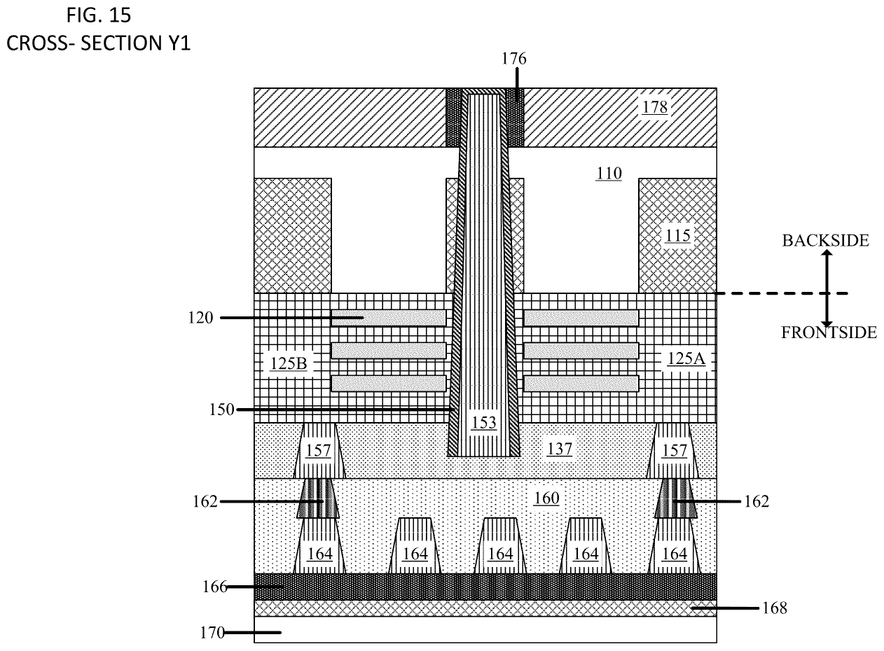

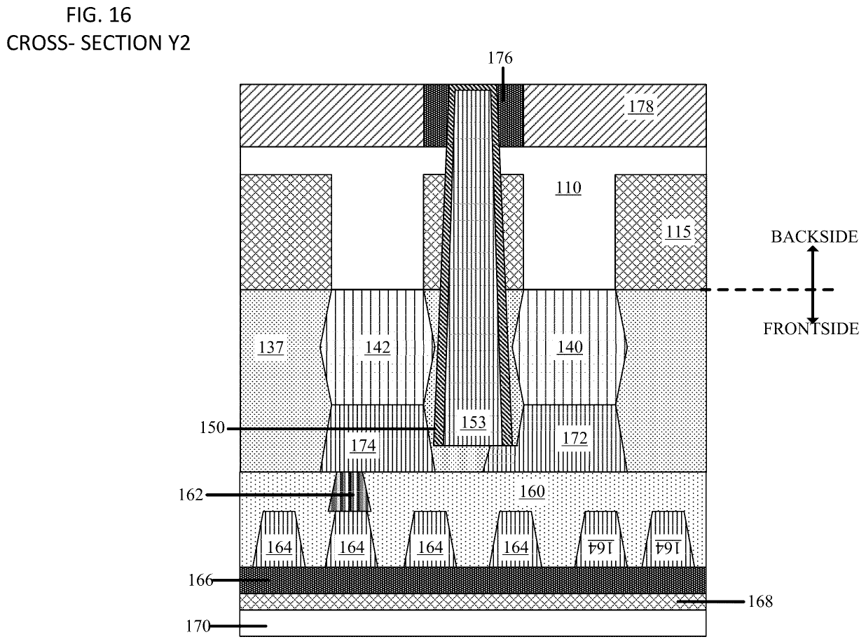

FIGS. 15 and 16 illustrate the processing stage after formation of a backside sacrificial spacer 176 and formation of a first backside interlayer dielectric layer 178. The etch stop 106 is removed to expose a backside surface of the second substrate 110. A backside sacrificial spacer 176 is formed around the exposed portions of the deep via liner 150. The backside sacrificial spacer 176 is in contact with a backside surface of the second substrate 110. The first backside interlayer dielectric layer 178 is formed on top of the backside surface of the second substrate 110 and around the backside sacrificial spacer 176. The first backside interlayer dielectric layer 178 and the backside sacrificial spacer 176 are planarized by, for example, chemical mechanical planarization (CMP), to expose a top surface of the deep via liner 150.

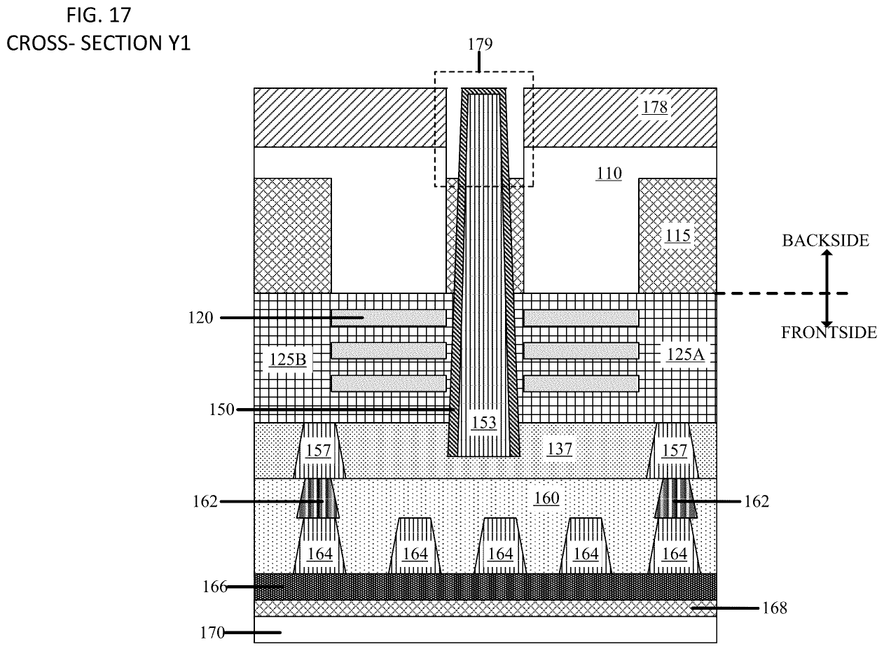

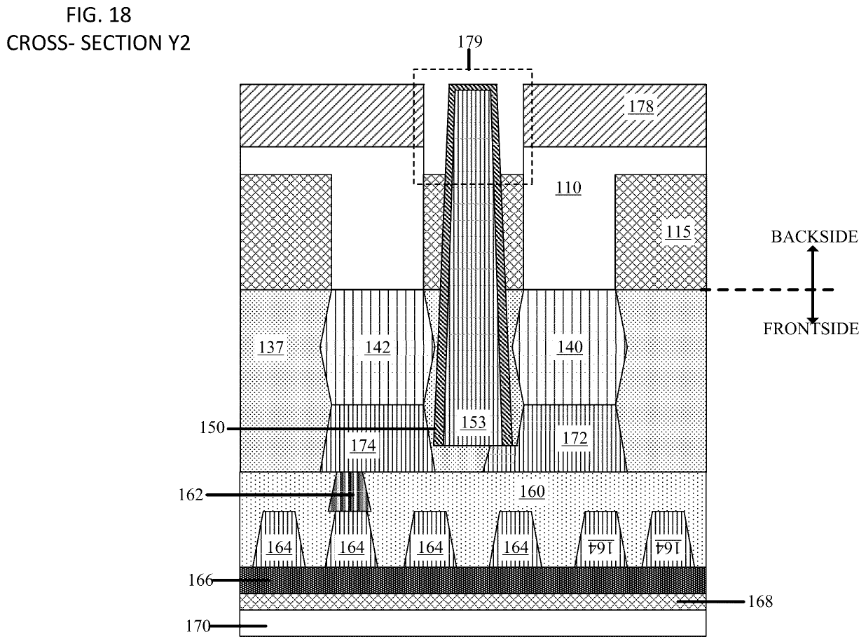

FIGS. 17 and 18 illustrate the processing stage after removal of the backside sacrificial spacer 176 and formation of a spacer trench 179. The backside sacrificial spacer 176 is removed to expose a portion of the second substrate 110. The second substrate 110 is partially etched to form a spacer trench 179 located around the deep via liner 150 and the deep via 153. Spacer trench 179 extends downwards to the backside surface of the shallow trench isolation layer 115. Spacer trench 179 exposes sidewalls of the second substrate 110 located adjacent to the deep via liner 150 and the deep via 153.

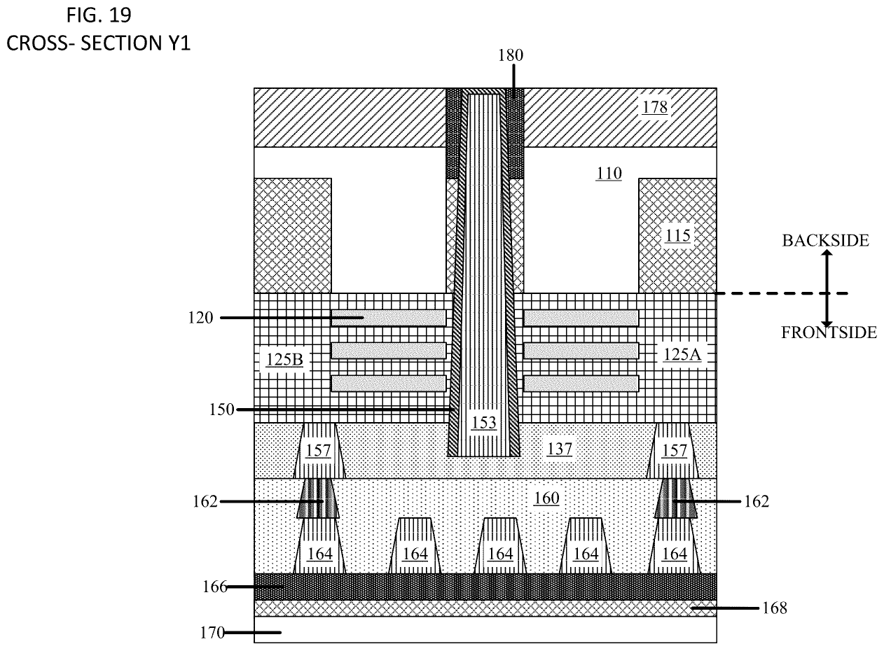

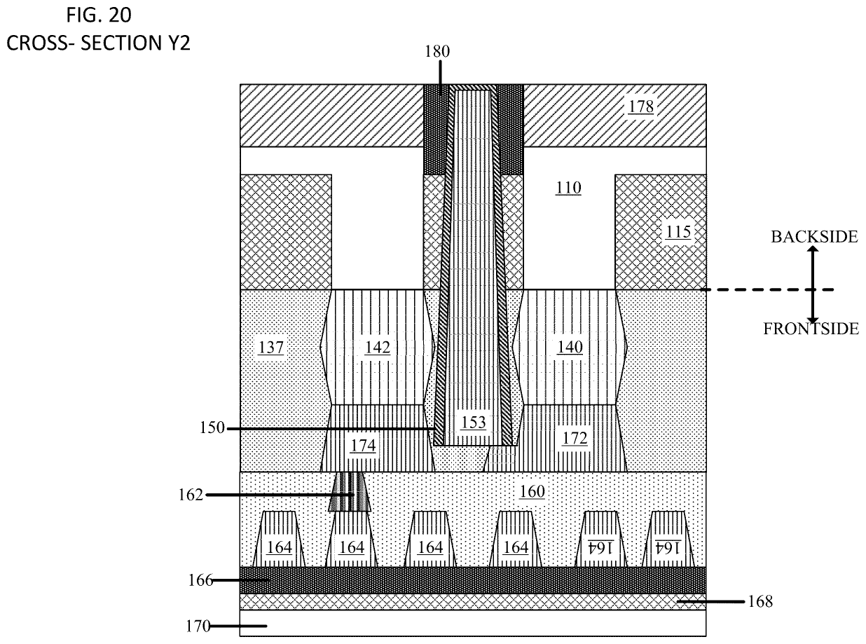

FIGS. 19 and 20 illustrate the processing stage after formation of a backside spacer 180. Spacer trench 179 is filled in with spacer material to form the backside spacer 180. The backside spacer 180 is in contact with the vertical sidewalls of the deep via liner 150, the vertical sidewalls of the second substrate 110, and the vertical sidewalls of the first backside interlayer dielectric layer 178. The backside spacer 180 is in contact with the backside surface of the shallow trench isolation layer 115.

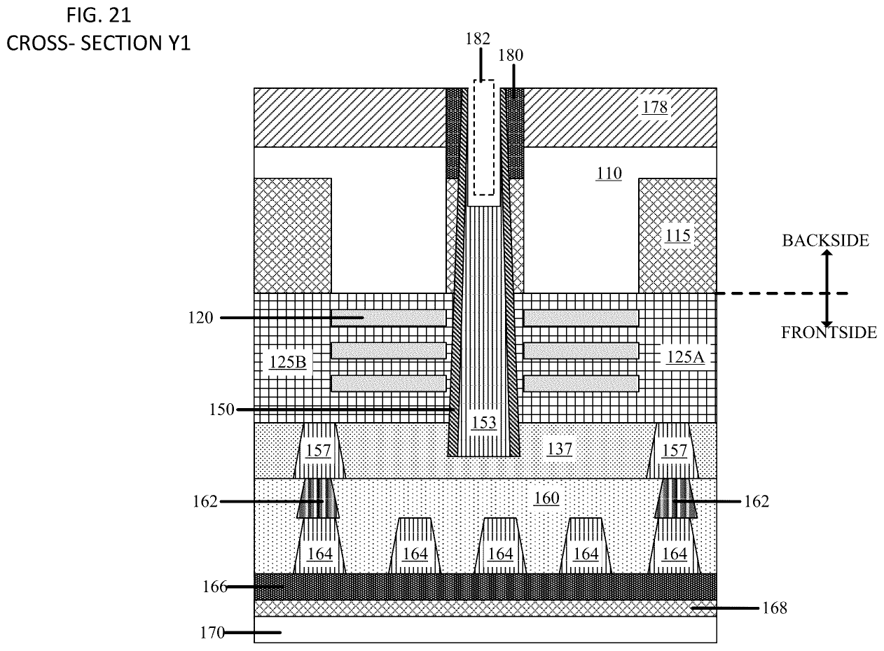

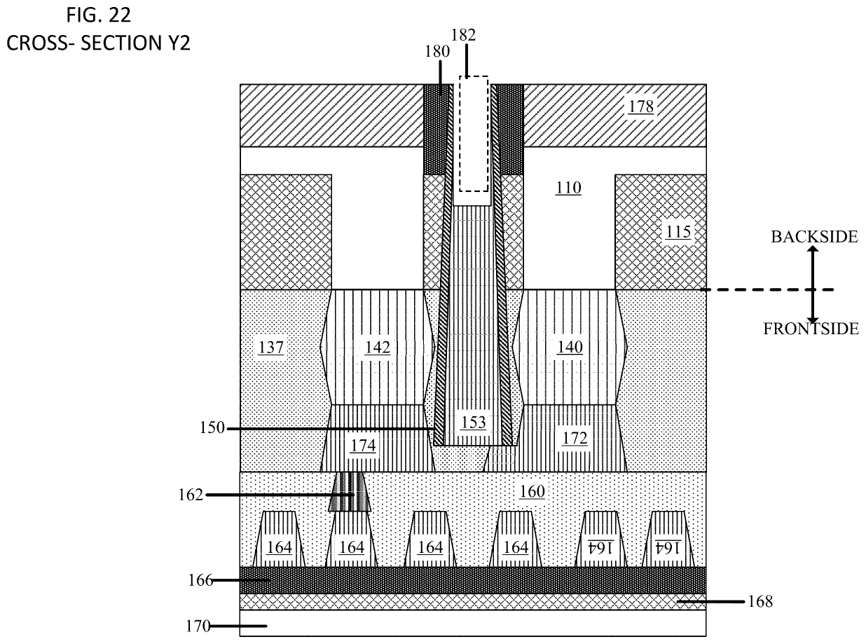

FIGS. 21 and 22 illustrate the processing stage after formation of an initial backside contact trench 182. An initial backside contact trench 182 is formed in the deep via 153. A portion of the deep via liner 150 and a portion of the deep via 153 is removed to form the initial backside contact trench 182. The backside contact trench 182 extends downwards past the bottom surface of the backside spacer 180 into the region or level of the shallow trench isolation layer 115.

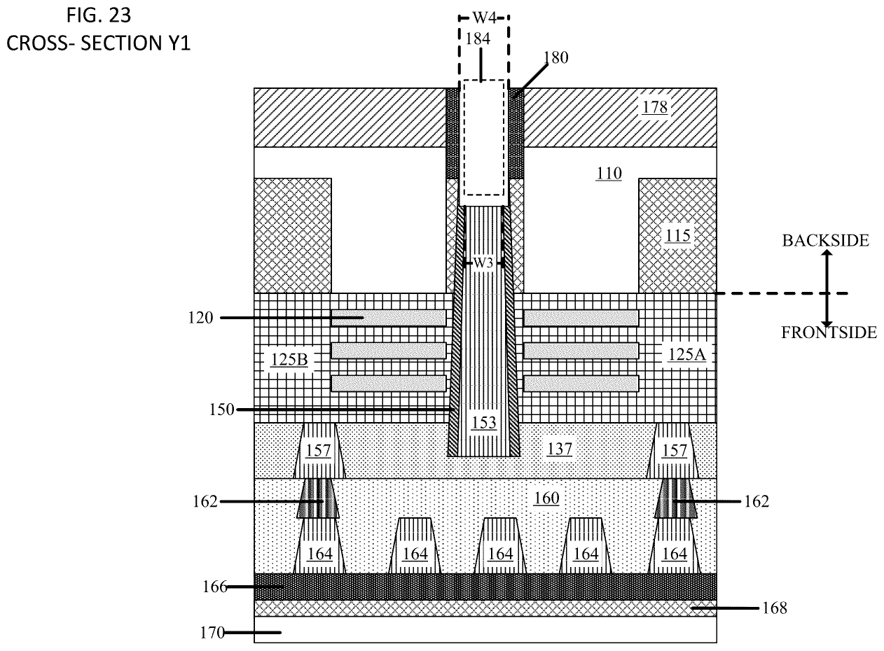

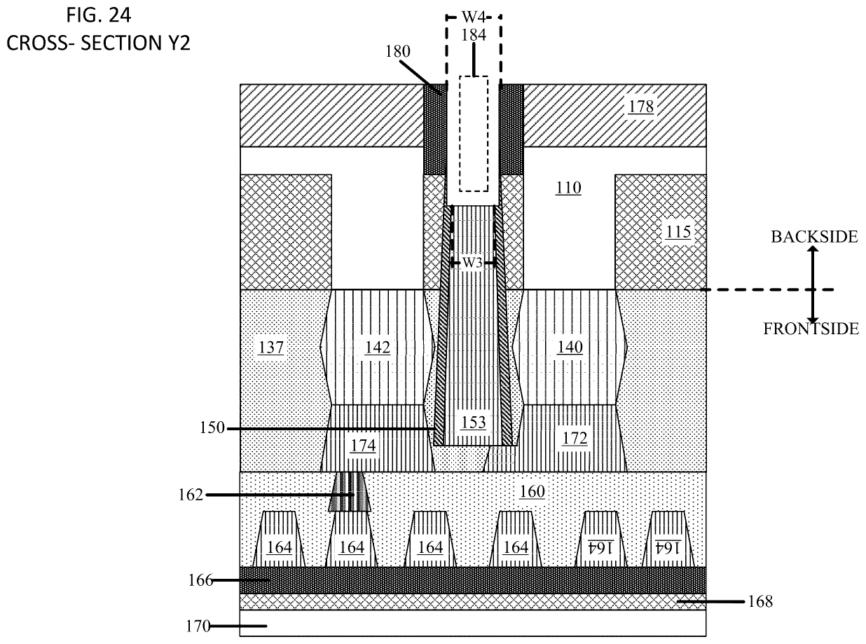

FIGS. 23 and 24 illustrate the processing stage after formation of a widened backside contact trench 184. The portions of the deep via liner 150 exposed by the backside contact trench 182 are selectively removed to create the widened backside contact trench 184. The exposed backside surface of the deep via 153 has a width W3, as measured in parallel to the gate direction. The widened backside contact trench 184 has a width W4, as measured in parallel to the gate direction. Width W4 of the widened backside contact trench 184 is larger than width W3 of the exposed backside surface of the deep via 153.

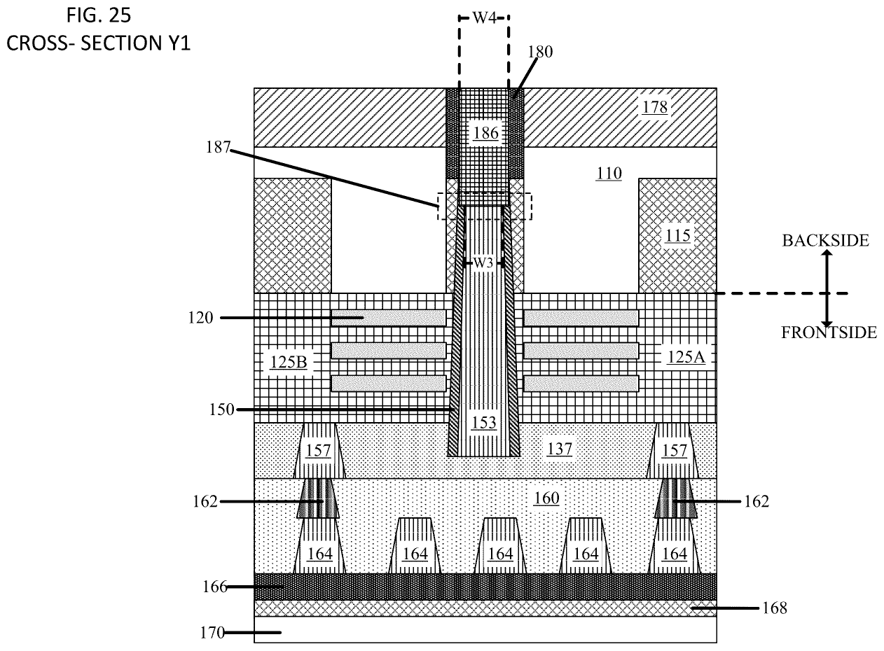

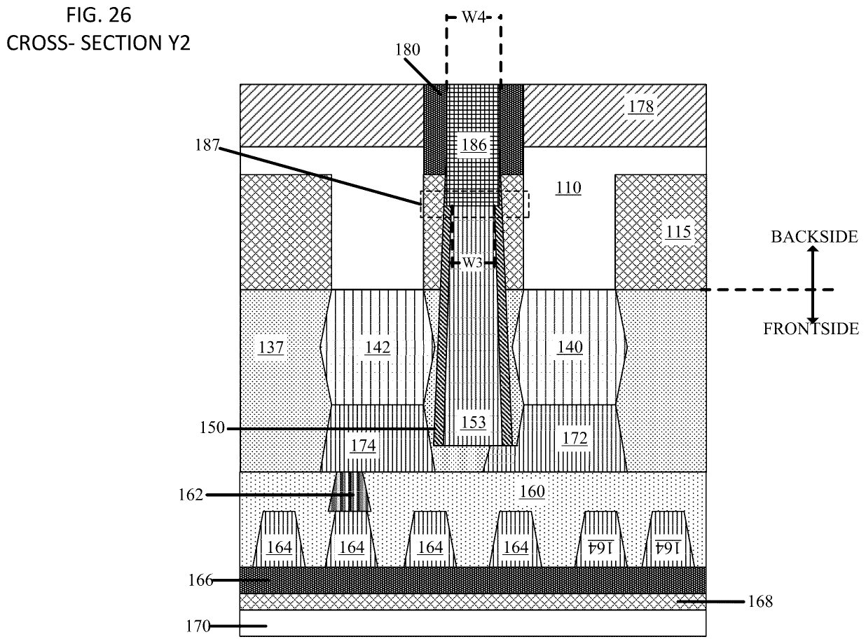

FIGS. 25 and 26 illustrate the processing stage after formation of a widened deep via extension 186. The widened backside contact trench 184 is filled with a conductive metal to form the widened deep via extension 186. The widened deep via extension 186 has the same width W4 as the widened backside contact trench 184. Dashed box 187 emphasizes the transition area between the deep via 153 and the widened deep via extension 186. The widen deep via extension 186 is wider than a backside surface contact area of the deep via 153. The difference between the widths causes a portion of the widened deep via extension 186 to extend past the backside contact surface area of the deep via 153 as emphasized by dashed box 187. Therefore, the bottom surface of the widened deep via extension 186 is in contact with deep via liner 150 and the deep via 153. The vertical sidewalls of the widened deep via extends 186 are in contact with the shallow trench isolation layer 115 and in contact with backside spacer 180.

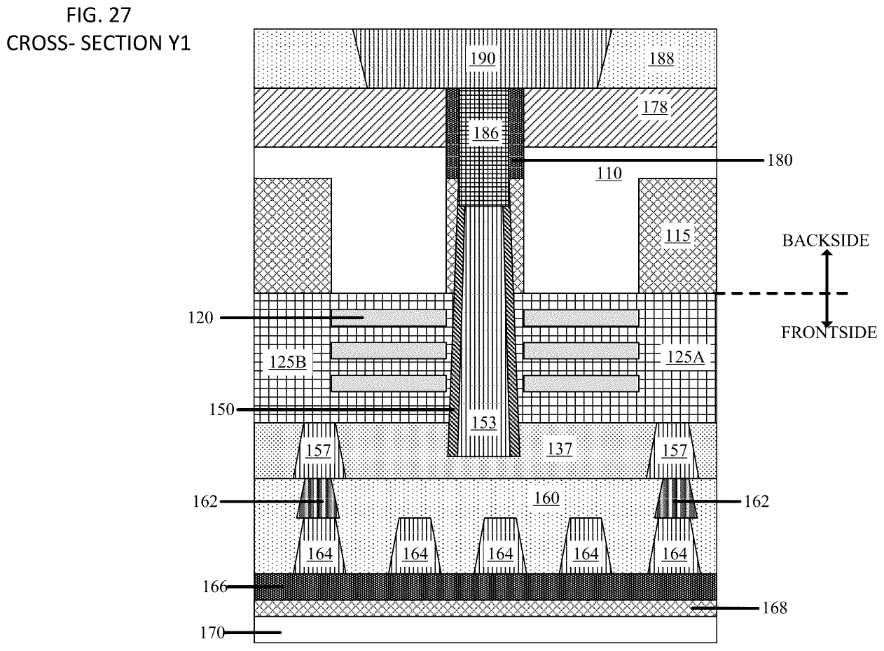

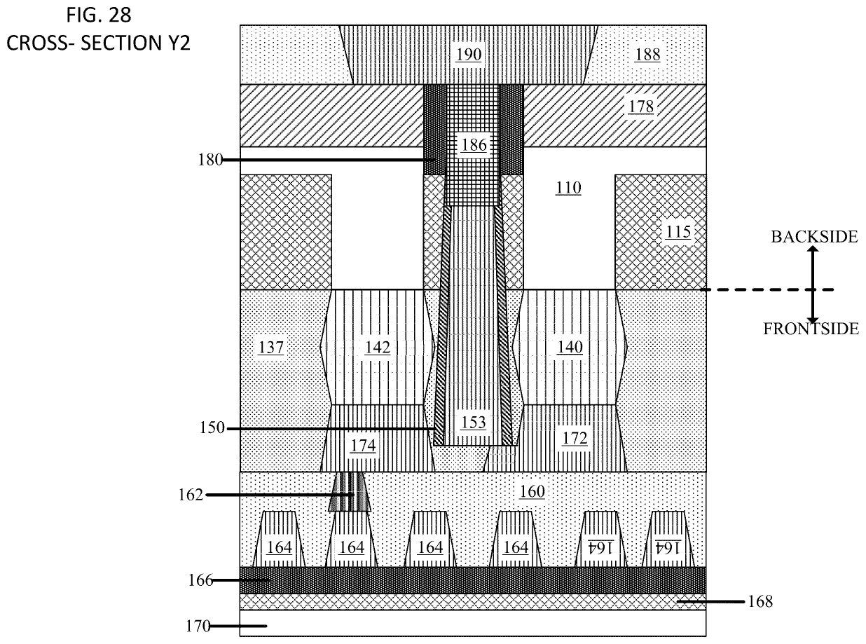

FIGS. 27 and 28 illustrate the processing stage after formation of a second backside interlayer dielectric layer 188 and formation of a backside metal line 190. A second backside interlayer dielectric layer 188 is formed on top of the first backside interlayer dielectric layer 178, on top of the backside spacer 180, and on top of the widened deep via extension 186. A trench (not shown) is formed in the second backside interlayer dielectric layer 188. A metallization process is utilized to fill the trench (not shown) to form a backside metal line 190. The bottom surface of the backside metal line 190 is in contact with the second backside interlayer dielectric layer 178, the backside spacer 180, and the widen deep via extension 186.

A microelectronic structure that includes a nanosheet FET (FIG. 27, 28) located on a substrate (second substrate 110) where the nanosheet FET includes a source/drain 140. A frontside source/drain contact 172 located on a frontside surface of the source/drain 140. A deep via 153 located adjacent to the frontside source/drain contact 172, where the frontside source/drain contact 172 is connected to the deep via 153. The deep via 153 extends downwards to a backside region of the nanosheet FET. A deep via extension 186 is located on a backside surface of the deep via 153, where the deep via extension 186 is wider than the backside surface of the deep via 153.

A shallow trench isolation layer 115 located within the substrate 110, where the deep via 153 extends into the shallow trench isolation layer 115. The deep via extension 186 extends into the shallow trench isolation layer 115. A backside spacer 180 located around the deep via extension 186. A sidewall of the backside spacer 180 is in contact with the substrate 110. A bottom surface of backside spacer 180 is in contact with the shallow trench isolation layer 115. A backside interlayer dielectric layer 178 is located on the backside surface of the substrate 110. The side wall of the backside spacer 180 is also in contact with the backside interlayer dielectric layer 178.

A microelectronic structure includes a nanosheet FET (FIGS. 27, 28) located on a substrate (second substrate 110) where the nanosheet FET includes a source/drain 140. A frontside source/drain contact 172 located on a frontside surface of the source/drain 140. A deep via 150, 153 located adjacent to the frontside source/drain contact 172. The deep via 150, 153 includes a conductive via 153 and a deep via liner 150, where the deep via liner 150 is located around the conductive via 153. The frontside source/drain contact 172 is connected to the deep via 153. The deep via 153 extends downwards to a backside region of the nanosheet FET. A deep via extension 186 is located on a backside surface of the deep via 153, where the deep via extension 186 is wider than the backside surface of the deep via 153.

A shallow trench isolation layer 115 located within the substrate 110, where the deep via 153 extends into the shallow trench isolation layer 115. The deep via liner 150 is in contact with the shallow trench isolation layer 115. The deep via extension 186 extends into the shallow trench isolation layer 115. A bottom surface of the deep via extension 186 is in with the conductive via 153 and the deep via liner 150. A backside spacer 180 located around the deep via extension 186. A sidewall of the backside spacer 180 is in contact with the substrate 110. A bottom surface of backside spacer 180 is in contact with the shallow trench isolation layer 115. A backside interlayer dielectric layer 178 is located on the backside surface of the substrate 110. The side wall of the backside spacer 180 is also in contact with the backside interlayer dielectric layer 178.

A microelectronic structure includes a nanosheet FET (FIGS. 27, 28) located on a substrate (second substrate 110) where the nanosheet FET includes a source/drain 140. A frontside source/drain contact 172 located on a frontside surface of the source/drain 140. A deep via 150, 153 located adjacent to the frontside source/drain contact 172. The deep via 150, 153 includes a conductive via 153 and a deep via liner 150, where the deep via liner 150 is located around the conductive via 153. The frontside source/drain contact 172 is connected to the deep via 153. The deep via 153 extends downwards to a backside region of the nanosheet FET. A deep via extension 186 is located on a backside surface of the deep via 153, where the deep via extension 186 is wider than the backside surface of the deep via 153. A first backside interlayer dielectric layer 178 is located on a backside surface of the substrate 110. A second backside interlayer dielectric layer 188 is located on a backside surface of the first interlayer dielectric layer 178.

A backside spacer 180 located around the deep via extension 186. A sidewall of the backside spacer 180 is in contact with the substrate 110.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a nanosheet FET located on a substrate, wherein the nanosheet FET includes a source/drain;
a frontside source/drain contact located on a frontside surface of the source/drain;
a deep via located adjacent to the frontside source/drain contact, wherein the frontside source/drain contact is connected to the deep via, wherein the deep via extends downwards to a backside region of the nanosheet FET; and
a deep via extension is located on a backside surface of the deep via, wherein the deep via extension is wider than the backside surface of the deep via.

2. The microelectronic structure of claim 1, further comprising;
a shallow trench isolation layer located within the substrate, wherein the deep via extends into the shallow trench isolation layer.

3. The microelectronic structure of claim 2, wherein the deep via extension extends into the shallow trench isolation layer.

4. The microelectronic structure of claim 3, further comprising:
a backside spacer located around the deep via extension.

5. The microelectronic structure of claim 4, wherein a sidewall of the backside spacer is in contact with the substrate.

6. The microelectronic structure of claim 5, wherein a bottom surface of backside spacer is in contact with the shallow trench isolation layer.

7. The microelectronic structure of claim 6, further comprising:
a backside interlayer dielectric layer is located on the backside surface of the substrate.

8. The microelectronic structure of claim 7, wherein the sidewall of the backside spacer is also in contact with the backside interlayer dielectric layer.

9. A microelectronic structure comprising:
a nanosheet FET located on a substrate, wherein the nanosheet FET includes a source/drain;
a frontside source/drain contact located on a frontside surface of the source/drain;
a deep via located adjacent to the frontside source/drain contact, wherein the deep via includes a conductive via and a deep via liner, wherein the deep via liner is located around the conductive via, wherein the frontside source/drain contact is connected to the deep via, wherein the deep via extends downwards to a backside region of the nanosheet FET; and
a deep via extension is located on a backside surface of the deep via, wherein the deep via extension is wider than the backside surface of the deep via.

10. The microelectronic structure of claim 9, further comprising;
a shallow trench isolation layer located within the substrate, wherein the deep via extends into the shallow trench isolation layer, wherein the deep via liner is in contact with the shallow trench isolation layer.

11. The microelectronic structure of claim 10, wherein the deep via extension extends into the shallow trench isolation layer.

12. The microelectronic structure of claim 11, wherein a bottom surface of the deep via extension is in contact with the conductive via and the deep via liner.

13. The microelectronic structure of claim 12, further comprising:
a backside spacer located around the deep via extension.

14. The microelectronic structure of claim 13, wherein a sidewall of the backside spacer is in contact with the substrate.

15. The microelectronic structure of claim 14, wherein a bottom surface of backside spacer is in contact with the shallow trench isolation layer.

16. The microelectronic structure of claim 15, further comprising:
a backside interlayer dielectric layer is located on the backside surface of the substrate.

17. The microelectronic structure of claim 16, wherein the sidewall of the backside spacer is also in contact with the backside interlayer dielectric layer.

18. A microelectronic structure comprising:
a nanosheet FET located on a substrate, wherein the nanosheet FET includes a source/drain;
a frontside source/drain contact located on a frontside surface of the source/drain;
a deep via located adjacent to the frontside source/drain contact, wherein the deep via includes a conductive via and a deep via liner, wherein the deep via liner is located around the conductive via, wherein the frontside source/drain contact is connected to the deep via, wherein the deep via extends downwards to a backside region of the nanosheet FET;
a deep via extension is located on a backside surface of the deep via, wherein the deep via extension is wider than the backside surface of the deep via;
a first backside interlayer dielectric layer is located on a backside surface of the substrate; and
a second backside interlayer dielectric layer is located on a backside surface of the first interlayer dielectric layer.

19. The microelectronic structure of claim 18, further comprising:
a backside spacer located around the deep via extension.

20. The microelectronic structure of claim 19, wherein a sidewall of the backside spacer is in contact with the substrate.
